(19) United States
(12) Patent Application Publication
(10) Pub. No.: US 2012/0175585 A1
(43) Pub. Date: Jul. 12, 2012

(54) CAGE NANOSTRUCTURES AND PREPARTION THEREOF

(75) Inventors: Uri Banin, Mevasseret Zion (IL); Elizabeth Janet Macdonald, Jerusalem (IL)

(73) Assignee: YISSUM RESEARCH DEVELOPMENT COMPANY OF THE HEBREW UNIVERSITY OF JERUSALEM, LTD.,, Jerusalem (IL)

(21) Appl. No.: 13/496,359

(22) PCT Filed: Sep. 16, 2010
(86) PCT No.: PCT/IL10/00758

§ 371 Date: Mar. 15, 2012

Related U.S. Application Data
(60) Provisional application No. 61/243,243, filed on Sep. 17, 2009.

(51) Int. Cl. H01L 29/66; H01L 21/20; H01L 21/26; B82Y 40/00; B82Y 99/00

(52) U.S. Cl. 257/12; 438/478; 438/795; 257/E29.168; 257/E21.09; 257/E21.328; 977/774; 977/891

(57) ABSTRACT

A unique family of nanoparticles characterized by their nanometric size and cage-like shapes (hollow structures), capable of holding in their hollow cavity a variety of materials is disclosed herein.

### FIELD OF THE INVENTION

This invention relates to cage nanostructures and preparation thereof.

### BACKGROUND OF THE INVENTION

Semiconducting nanoparticles have several size-dependant properties that can improve their behavior for desired applications compared to bulk semiconductors. Nanoparticles have significantly increased surface areas and more molecules may be adsorbed to the surfaces. This speeds surface-catalyzed and surface-mediated reactions. This enhanced surface-to-volume ratio also has important consequences for applications such as gas storage and gas or solution separations.

In the case of photocatalyzed reactions, the semiconducting nanoparticle absorbs light causing the formation of an exciton (electron and hole-pair). The hole and/or electron may be transferred to a nearby molecule or material to induce chemical change [1]. In this manner, energy from light can be transferred to and stored as chemical energy. Additionally, such photocatalysis has applications in self-cleaning surfaces.

In photovoltaics the principal is similar. Light is absorbed by the particles forming excitons. A charge separation stage needs to follow and the photo induced electron and hole travel through the device in different directions and are transferred to an electrical circuit to do work. Apart from having more surfaces to mediate electron transfer to molecules, the small size of the particle decreases the spatial distance the photoexcited electron or hole needs to travel in order to reach the surface. This maximizes efficiency by reducing losses from competing electron-hole recombination processes in the particle.

One of the most interesting features of semiconducting nanoparticles is the size-dependence of the band gap. As particles get smaller, the band gap of the semiconductor widens. In this manner, the optical and electronic properties such as the optical absorbance, fluorescence, and the position of the conduction or valence band levels can be tuned according to the needs of the application. Additionally, the position of the band gap with respect to vacuum can be tuned with the use of surface ligands with electron withdrawing and electron donating groups [2].

Xia et al [3-12] has developed galvanic displacement processes for producing nanostructures having hollow interiors and porous walls. The process developed involves treating Ag nanostructures under galvanic displacement reaction conditions with a metal precursor salt, e.g., gold. The electrochemical potential difference between the two species drives the reaction, resulting in epitaxial deposition of gold atoms on the surface of the Ag nanostructures. In the next stage, a dealloying agent, i.e., an etchant, is used to selectively dissolve the Ag from the Au/Ag alloyed nanostructures. In the etching process, porosity is introduced with a degree of porosity being dependent on the amount of etchant employed. When all the Ag is removed, the central portions of the nanostructure disappear, producing a nanoframe composed of Au atoms [8].

As known, dealloying of an electrochemically more active element in an alloy results in the formation of a nanoporous sponge, composed almost entirely of the more noble alloy constituent. This tendency has permitted the formation of high surface area of nanoporous gold nanostructures. It is thus understood that while the nanoframes of Xia et al [8] maintain the original morphology of the Ag nanostructures, the surface of the Au edges in the nanoframes also demonstrate a degree of porosity.

### REFERENCES

[1] Banin et. al., Nano Letters (2008) 2, 637
[2] Banin et al., Nano Letters (2008) 2, 678
[3] Xia et al., Accounts of Chemical Research (2008) 41, 1587-1595
[4] Xia et al., Journal of the American Chemical Society (2006) 128, 14776-14777
[5] Xia et al., Nature Protocols (2007) 2, 2182-2190
[6] Xia et al., Nature Materials (2009) 8, 935-939
[7] Xia et al., Advanced Materials (2008) 20, 2517-2522
[8] Xia et al., Nano Letters (2007) 7, 1764-1769
[9] U.S. Pat. No. 7,585,349
[10] US Patent Application No. 2008/0003130
[11] US Patent Application No. 2009/0297388
[12] US Patent Application No. 2009/0282948
[13] Alivisatos et al., Nano Letters, (2008) 8, 2551
[14] Tang et al., Journal of the American Chemical Society (2008) 39, 13152
[15] Wu et al., Journal of Physics and Chemistry of Solids (2006) 67, 1786
[16] Park et al., Journal of Physical Chemistry (2009) 113, 1251

### SUMMARY OF THE INVENTION

It is now the purpose of the present invention to provide a unique family of nanoparticles characterized by their nanometric size (having their shortest axis in the nanometric scale) and cage-like shape (hollow structures). The novel nanoparticles of the invention are referred to as NIC particles, Nano-Inorganic Cage particles, which, in some of the embodiments disclosed in the present application, are embodied as hybrid particles where the cage is composed of a first material, with the interior of the cage being composed of a second material and/or of a material of a different structure (shape). These hybrid structures are herein referred to as NICED particles, Nano-Inorganic CagED particles.

The NIC particles (herein used interchangeably with nanostructures), in fact, have the advantages typically assigned to nanoparticles, as discussed above, and in addition have numerous other advantages which stem from their unique cage shape. This shape endows these nanoparticles with structural integrity and further increased surface-area-to-material weight ratio, a clear advantage for their use as catalyst materials. As freestanding catalysts, the NIC particles are easily separated from reaction products as they have larger hydrodynamic radii than those of corresponding spherical particles with similar masses. In addition, the interior of the cages may be used as capsules or vehicles for another material, e.g., for storage or isolation of a secondary material for a specialized catalysis or delivery applications.

Thus, in one aspect of the present invention, there is provided a hollow nanostructure having a structure of a polyhedron skeleton, said polyhedron skeleton having a plurality of straight edges connected to each other via vertices, each of said straight edges being composed of a continuum of an inorganic material.

The nanostructure skeleton is thus a hollow structure, a frame, wherein a non-porous (at the resolution provided by available imaging techniques), chemically integral (continuum) of an inorganic material defines the skeleton structure. The faces formed between edges of the polyhedron are material-free.

Thus, in some embodiments, there is provided a hollow nanostructure having a structure of a polyhedron skeleton, said polyhedron skeleton having a plurality of straight edges connected to each other via vertices, each of said straight edges being composed of a continuum of a non-porous inorganic material.

As a person skilled in the art would appreciate, a “polyhedron” is a geometric structure having flat faces connected to each other via straight edges. Each edge joins one corner point, the so-called vertex, to another and one face to another, and is usually a line segment. The edges together make up the polyhedral skeleton. In the hollow nanostructures of the invention, the faces of the polyhedron skeleton are material-free. The “structure” or shape of the nanostructure of the invention is the three-dimensional assembly of the inorganic material which is arranged as a polyhedron. In some embodiments, the polyhedron is not a cubic structure. In other embodiments, the polyhedron is not a gold cubic nanostructure.

Similarly, the term “cage” or any lingual variation thereof refers to the cavity of the polyhedron structure which is generated by the intersection of interconnected three-dimensional network defined by the edges.

The NIC particles are 2 to 500 nm in size (averaged diameter). In some embodiments, the NIC particles are 2 to 100 nm in size.

The NIC particles are hollow three-dimensional structures with each of the straight edges being substantially a quasi one dimensional line structure; namely, each edge line ranging in thickness from 0.5 nm (1-2 atom thickness) to 10 nm or more. The straight continuous and non-porous edges of the NIC particles may or may not be a monolayer of atoms.

The NIC particles are not molecular cages, namely, their structure is not defined by the orientation in space of one or more chemical bond. The three-dimensional structure of an exemplary molecular cage is defined by the bonds between each atom positioned at the vertices. The lines connecting the vertices designate the chemical bonds. In contradiction, in a NIC particle according to the present invention, having for the purpose of this particular example the same polyhedron structure, the vertices and lines connecting them are composed of an inorganic material which is substantially a non-porous material continuum of an inorganic material which may be in an amorphous form, in a crystalline form or a polycrystalline form. In the NIC particles, the vertices do not define a relative position of an atom.

The NIC particles have a three-dimensional polyhedron structure which may or may not be symmetric. Unlike certain cage materials of the art, which may or may not be molecular cages, the NIC particles of the invention are not onion-like structures, namely each NIC particles is not a cage within a cage but rather a single cage material.

As known in the art, a polyhedron structure may be a regular, an irregular or a distorted polyhedron, a semiregular or a quasiregular polyhedron. The polyhedron shape of the NIC particles of the invention is defined, in some embodiments, by the number, n, of faces the polyhedron has. In some embodiments, the NIC particles of the invention are defined by n being between 4 and 90.

In some embodiments, the polyhedron shape is selected from a tetrahedron (pyramid), a hexahedron, an octahedron, a dodecahedron, tetradecahedron, and an icosahedron. In some embodiments, the hexahedron shape excludes a shape where all its faces are square (cube), i.e., the hexahedron is different from a cube.

The inorganic nanostructures of the invention are composed of a single or a mixture of inorganic compounds which are made to form the polyhedron shape. Each section of the NIC structure is composed of a continuum of an inorganic material which may be amorphous or in the form of a plurality of multitude of material crystallites, which may be oriented randomly, or crystalline (single crystal). For example, where the inorganic material is Ru, the Ru NIC particles may each be constructed of a plurality of Ru crystallites forming, the polyhedral shapes, where typically the crystallite size may range from about 1 to about 10 nm or may be of an amorphous Ru material. In some other examples, the NIC particle may be composed of a mixture of crystalline and amorphous Ru, wherein certain regions of the particle are of a crystalline Ru and others are of an amorphous Ru.

As stated hereinabove, the NIC particles are composed of an inorganic material which may be in a crystalline form and/or an amorphous form. The inorganic material may be selected from a metal, a transition metal, a semiconductor, an insulator or any alloy or any intermetallic material.

In some embodiments, the inorganic material is or comprises an element of Groups IIIB, IVB, VB, VIIB, VIIB, VIIIB, IB, IIB, IIIA, IVA and VA of block d of the Periodic Table of the Elements.

In some embodiments, the inorganic material is or comprises a transition metal selected from Groups IIIB, IVB, VB, VIIB, VIIB, VIIIB, IB and IIB of block d the Periodic Table. In some embodiments, the transition metal is a metal selected from Sc, Ti, V, Cr, Mn, Fe, Ni, Cu, Zn, Y, Zr, Nb, Tc, Ru, Mo, Rh, W, Au, Pt, Pd, Ag, Mn, Co, Cd, Hf, Ta, Re, Os, Ir and Hg. In some additional embodiments, the inorganic material is or comprises a transition metal selected from Ru, Mo, Th and W. In other embodiments, the inorganic material comprises Ru.

In some embodiments, where the polyhedron shape is cubic, the inorganic material making up the NIC particles is different from gold.

Thus, in some embodiments, the invention also provides a hollow nanostructure having a structure defined by the edges of a polyhedron, each of said edges being composed of a continuum of inorganic material, excluding gold hollow nanostructures, e.g., in the form of nanocubes.

Also provided is a hollow nanostructure having a structure defined by the edges of a polyhedron, each of said edges being composed of a continuum of inorganic material, wherein said hollow nanostructure is not a nanocube, e.g., of gold.

Differently put, there is also provided a hollow nanostructure having a structure of a polyhedron skeleton, said polyhedron skeleton having a plurality of straight edges connected to each other via vertices, each of said straight edges being composed of a continuum of a non-porous inorganic material, excluding gold cube nanostructures.

In other embodiments, the NIC particles are composed of a material selected from a semiconductor or an insulator.

In some embodiments, the semiconductor material is selected from elements of Group II-VI, Group III-V, Group IV-VI, Group III-VI, Group IV semiconductors and combinations thereof.

In other embodiments, the semiconductor material is a Group II-VI material being selected from CdSe, CdS, CdTe, ZnSe, ZnS, ZnTe, HgS, HgSe, HgTe, CdZnSe and any combination thereof.

In further embodiments, Group III-V material are selected from InAs, InP, InN, GaN, InSb, InAsP, InGaAs, GaAs, GaP, GaSb, AlP, AlN, AlAs, AlSb, CdSeTe, ZnCdSe and any combination thereof.

In additional embodiments, the semiconductor material is selected from Group IV-VI, the material being selected from PbSe, PbTe, PbS, PbSnTe, Tl₂SnTe₅ and any combination thereof.

In other embodiments, the semiconductors are selected from RuS₂, RuO₂, MoS₂, MoO₃, RhS₂, RuO₄, WS₂ and WO₂.

In other embodiments, the NIC material is selected amongst metal alloys and intermetallics of the above metal and/or transition metals. Non-limiting examples of such alloys are WMo, MoRh, MoRh₃, Rh_{0.34}Ru_{0.66}, Rh_{0.4}Ru_{0.6}, PdRh, PdRu, MoPd₂, Pd_{0.3}Mo_{0.8}, MoPt, Mo₂Pt, PtPd, Pt_{0.4}Ru_{0.6}, N_{0.2}Ru_{0.8}, PtRh, WPt, AuPd, AuPt, AuRh, AuRu, AuMo, and AuW.

The present invention further provides in another of its aspects a method for the preparation of a nano-inorganic cage, NIC, according to the invention, the method comprising:

(a) providing a nanoparticle of a first inorganic material, said nanoparticle having a polyhedron structure;

(b) contacting said nanoparticle with a second inorganic material, or a precursor thereof, under conditions permitting deposition of said second inorganic material onto the edges of the polyhedron structure of said nanoparticle, to obtain a caged nanoparticle of said first material; namely a hybrid of the first and second materials (being herein referred to as Nano Inorganic Caged, NICed, particle, as further disclosed hereinbelow); and

(c) selectively disintegrating the first inorganic material to thereby obtain a substantially hollow nano-inorganic cage, NIC, of a second inorganic material, according to the invention.

In some embodiments, the nanoparticles of the first inorganic material of step (a) are contacted in solution with the second inorganic material or a precursor thereof of step (b). In the method of the invention, where a precursor to the second inorganic material is employed, the conversion of the precursor to the actual inorganic material forming the cage structure takes place under the condition exemplified herein.

The size and shape of the nanoparticles of the invention may be controlled by changing the size and shape of the original seed, e.g., Cu₂S seed nanoparticle, by changing at least one reaction parameter such as reaction times, temperatures, concentrations of seed and/or precursor materials, and/or surfactants.

In some embodiments, the formation of the NICed particles takes place in solution, optionally in the presence of a surfactant, at a temperature above room temperature (21-35° C.).

The solvent employed is typically an organic solvent system, which may comprise a single organic solvent or a mixture of such solvents. In some embodiments, the solvent, or the solvent system has a boiling point higher than 100° C. In further embodiments, the solvent has a boiling point not exceeding 250° C. Non-limiting examples of such solvents include toluene, benzyl ether, octylether, tetracosane, octacosane, and others, or mixtures thereof.

In other embodiments, the reaction temperature exceeds 100° C. In further embodiments, the reaction temperature is between about 100 and 200° C. In further embodiments, the reaction temperature is above about 200° C., above about 210° C., above about 220° C., above about 230° C., above about 240° C., above about 250° C. or above about 260° C. or at any temperature there between. In other embodiments, lower temperature is used, above the solvent freezing point.

In some embodiments, the NICed particles of step (b) are formed in the presence of at least one surfactant. Different surfactants bind to different crystal facets with varying strengths, thus influencing the size and shape of the resulting particles. Surfactants may include aliphatic thiols such as dodecanethiol and hexadecanethiol; amines such as oleylamine, dodecylamine, hexadecylamine, octadecylamine; carboxylic acids such as oleic acid or stearic acid; alcohols such as 1,2-hexadecanediol; phosphines such as trioctylphosphine; or phosphine oxides such as trioctylphosphine oxide; phosphonic acids such as hexylphosphonic acid, etc.

Without wishing to be bound by theory, the deposition of the inorganic material substantially onto the edges of the polyhedron structure of the nanoparticle core is likely driven by the higher energy of the crystal edge as atoms at the edge generally do not have all of their bonds satisfied, and also are under enhanced strain. Indeed, as a person skilled in the art would appreciate, prior art in hybrid nanoparticles so far led to deposition on one or more of the faces of a crystal seed. Material deposition substantially or mainly on the edges of a crystal seed has never been demonstrated before. Notwithstanding, NIC and caged nanoparticles (obtained from step (b) of the above method of the invention), where material also partially grows on the faces of a crystal seed, are also within the scope of the present invention.

As indicated hereinabove, prior technologies for the preparation of nanocages, or nanoframes have employed a different strategy. Rather than using material deposition as means to construct the frame of the nanostructure, as disclosed in the present application, means for material removal have been selectively employed. The material removal steps have been known to effect material integrity and constitution of the final nanostructure. Unlike such early processes, in the process of the invention, the deposition of the second material on the edges of the polyhedron nanostructure permits formation of a material continuum of a controlled thickness, which intimately follows the contour of the polyhedron edges. As this material continuum does not contain any of the material to be disintegrated, the selective disintegration of the first organic material does not affect the morphology or constitution of the second material, or its overall polyhedron shape. The resulting nano-inorganic NIC particles thus exhibit non-porosity of edge material, in direct contrast to what is expected when other processes, particularly those employing material removal, e.g., etching, are used [8].

The hybrid nanostructures of the core and nanostructure materials (the Nano Inorganic Caged, NICed, particles), being novel products according to the invention, also provide a unique family of hybrid semiconducting materials where particles of one material are encased by NIC particles of a different material.

The invention, thus, provides in another of its aspects a hybrid nanostructure comprising a core material (i.e., the first inorganic material) being in the form of a polyhedron defined by a plurality of faces connected to each other via straight edges, said core material having a continuum of a different inorganic material (i.e., the second inorganic material) substantially only on its edges. In other words, the faces of the polyhedron formed are substantially material-free.

The NICed particles are, in some embodiments, semiconducting nanoparticles, having all of the advantages associated with other semiconducting materials. One additional advantage relates to the potential of the synergistic properties of the two materials making the hybrid particle, namely the material of the NIC and that of the NICed core material. Additional advantage of the hybrid metal-semiconducting nanoparticles is their bifunctionality. For example, if one material, e.g., the semiconductor, absorbs light to make an exciton, the hole or electron may be readily transferred to the second material, e.g., the metal. This minimizes losses from electron-hole recombination in photovoltaics and photocatalysis applications. Moreover, the second material may not be as efficient at light absorbance, but may have highly desirable surfaces for catalysis. Also, the two materials may provide separately two separate steps of a catalytic process; the short distance between the two parts will cause an increased rate of the overall catalytic process by circumventing otherwise necessary diffusion, adsorption and desorption processes. The interface between the two materials may also provide new catalytic sites in large amounts due to the size of the particles. As well, if the particles are deposited on an electrode, one part (e.g. the metal) may provide a percolating conducting path for electrons while the other (e.g. the semiconductor) providing the catalytic sites.

In the method of making NIC particles according to the invention, or for making NICed particles by employing steps (a) and (b) of the above disclosed method for making the NIC particles, the material of step (a) being a seed nanoparticle, e.g., a crystal, having a polyhedron shape may be selected based on its crystal shape, its chemical reactivity towards the cage material, its electronic properties, cost considerations and/or other considerations. In some embodiments, the seed nanoparticle material of step (a) of the method is selected based on its polyhedron shape. In other embodiments, the material is selected based on its ability to chemically interact with the material of the NIC.

In some embodiments, the first inorganic material is or composes of an element of Groups IIIB, IVB, VB, VIIB, VIIB, VIIIB, IB, IIB, IIIA, IVA and VA of block d of the Periodic Table of the Elements. In some embodiments, the element is selected from Sc, Ti, V, Cr, Mn, Fe, Ni, Cu, Zn, Y, Zr, Nb, Tc, Ru, Mo, Rh, W, Au, Pt, Pd, Ag, Mn, Co, Cd, Hf, Ta, Re, Os, Ir and Hg.

In further embodiments, the second inorganic material is or composes an element of Groups IIIB, IVB, VB, VIIB, VIIB, VIIIB, IB, IIB, IIIA, IVA and VA of block d of the Periodic Table of the Elements. Similarly, the element may be selected from Sc, Ti, V, Cr, Mn, Fe, Ni, Cu, Zn, Y, Zr, Nb, Tc, Ru, Mo, Rh, W, Au, Pt, Pd, Ag, Mn, Co, Cd, Hf, Ta, Re, Os, Ir and Hg.

In further embodiments, the second inorganic material is or comprises a transition metal selected from Ru, Mo, Th and W.

In some embodiments, the first inorganic material is or composes a semiconductor material selected from Group II-VI, Group III-V, Group IV-VI, Group and/or Group IV semiconductors. The semiconductor material may be selected from CdSe, CdS, CdTe, ZnO, ZnSe, ZnS, ZnTe, HgS, HgSe, HgTe, CdZnSe, InAs, InP, InN, GaN, InSb, InAsP, InGaAs, GaAs, GaP, GaSb, AlP, AlN, AlAs, AlSb, CdSeTe, ZnCdSe, PbSe, PbTe, PbS, PbSnTe, Tl₂SnTe₅, RuS₂, RuO₂, MoS₂, MoO₃, RhS₂, RuO₄, TiO₂, WS₂ and WO₂.

In further embodiments, the second inorganic material composes a semiconductor material selected from Group II-VI, Group III-V, Group IV-VI, Group and/or Group IV semiconductors. Such semiconductor material may be selected from CdSe, CdS, CdTe, ZnSe, ZnS, ZnTe, ZnO, TiO₂, HgS, HgSe, HgTe, CdZnSe, InAs, InP, InN, GaN, InSb, InAsP, InGaAs, GaAs, GaP, GaSb, AlP, AlN, AlAs, AlSb, CdSeTe, ZnCdSe, PbSe, PbTe, PbS, PbSnTe, Tl₂SnTe₅, RuS₂, RuO₂, MoS₂, MoO₃, RhS₂, RuO₄, WS₂ and WO₂.

In further embodiments, the first inorganic material around which the cage is formed is selected from copper sulfides, e.g., the copper sulfide being a ternary compound in the copper sulfide family, selected in a non-limiting manner from CuInS₂, CuGaS₂, CuAlS₂ and mixed copper-iron sulfides such as Cu₅FeS₄ (Bornite) and CuFeS₂ (chalcopyrite).

One advantage relating to the copper sulfides and the ternary copper sulfides is their very large extinction coefficients. As such, in solar energy and other photo mediated applications they absorb much of the light with only a very small amount of material. Moreover, copper sulfide is an abundant, cost effective and environmentally friendly material.

In some embodiments, in the hybrid structures of the invention, the second inorganic material is of a material selected from Ru, Mo, Rh, W, CdSe, CdS, CdTe, ZnSe, ZnS, ZnTe, HgS, HgSe, HgTe, CdZnSe, InAs, InP, InN, GaN, InSb, InAsP, InGaAs, GaAs, GaP, GaSb, AlP, AlN, AlAs, AlSb, CdSeTe, ZnCdSe, PbSe, PbTe, PbS, PbSnTe, Tl₂SnTe₅, RuS₂, RuO₂, MoS₂, MoO₃, RhS₂, RuO₄, WS₂ and WO₂ and the first inorganic material is selected amongst copper sulfides. In some further embodiments, the second inorganic material is of a material selected from Ru, Mo, Rh, W, RuS₂, RuO₂, MoS₂, MoO₃, RhS₂, RuO₄, WS₂ and WO₂ and said first inorganic material is Cu₂S.

In some embodiments, the copper sulfide is used as a precursor to other semiconducting nanoparticles. As is known, copper (I) sulfides form layer structures; the sulfurs form close packed hexagonal layers and the coppers reside in positions therebetween. Above ˜100° C., the copper atoms become mobile leading to a simplification of the complicated low temperature crystal structures to a hexagonal one, higher redox activity and ready ion dissolution and exchange. By an exchange with other metal cations, Cu₂S nanoparticles are therefore a gateway material to nanoparticles of other sulfides and mixed copper sulfides. The different copper sulfides have band gaps ranging from the near-IR (CuFeS₂) throughout the visible (Cu₂S, CuInS₂, CuGaS₂) into the UV (CuAlS₂) making them a versatile family for light based applications such as photocatalysis and photovoltaics. Other sulfides may include CdS or PbS.

Thus, generally the reaction of the caged particles with appropriate cations in the presence of an additional sulfur source will yield other sulfides including CuInS₂, CuFeS₂, CuGaS₂, Cu(InGa)S₂, CuAlS₂, AgS, Cu₂(ZnSn)S₄, CdS, PbS etc. In this manner hybrid materials between these sulfides and the aforementioned cage materials can be prepared. The reagents may be indium(III) acetate, indium(III) chloride, indium(III) nitrate, indium(III) acetylacetonate, for the creation of CuInS₂ and Cu(InGa)S₂; iron(II) chloride, iron(III) chloride, iron(II) acetate, iron(III) acetylacetonate for the formation of CuFeS₂; gallium(III) acetylacetonate, gallium(II) chloride, gallium(III) chloride, gallium(III) nitrate for the formation of CuGaS₂ and Cu(InGa)S₂; aluminum(III) chloride, aluminum(III) stearate for the formation of CuAlS₂; silver nitrate, silver chloride for the formation of AgS; dimethlyzinc, diethylzinc, zinc chloride, tin(II) chloride, tin(IV) chloride, tin(II) acetylacetonate, tin(II) acetate for the formation of Cu₂(ZnSn)S₄; cadmium(II) chloride, cadmium(II) nitrate, cadmium(II) acetate, cadmium(II) acetylyacetonate, cadmium(II) stearate for CdS; lead(II) acetate, lead(II) acetylylacetonate, lead(II) chloride, lead(II) nitrate for PbS, etc. The sulfur source may be elemental sulfur, thiourea, carbon disulfide, and alkyl thiols such as dodecanethiol, hexanethiol, etc. for all of the aforementioned sulfides.

Similarly, the speciation of the cage material may be changed by changing the Ru precursor to other materials. In this manner the cage material may be selected from Ru, Mo, Rh, W etc; reaction with sulfur may yield hybrid nanoparticles with cages of RuS₂, MoS₂, RhS₂, WS₂, etc. Oxidation may yield hybrid nanoparticles with cages of MoO₃, RuO₂, RuO₄, WO₂, etc. Furthermore, hybrid structures with metal components are formed by reaction with gold, palladium or platinum ions. Suitable regents include ruthenium(III) acetylacetonate, ruthenium(III) chloride, ruthenium(III) acetate, for the formation Ru, RuS₂, RuO₂, RuO₄; molybdenum(IV) chloride, molybdenum(V) chloride, molybdenum(VI) chloride, molybdenum(II) acetate, for the formation of Mo, MoS₂ and MoO₃; tungsten(IV) chloride, tungsten(VI) chloride, for the formation of W, WS₂ and WO₂; rhodium(III) acetylacetonate, rhodium(III) chloride, rhodium(III) nitrate for the formation of Rh, RhS₂; gold(III) chloride, gold(I) chloride, for the formation of gold; palladium(II) nitrate, palladium(II) chloride, palladium(II) acetate, palladium(II) acetylacetonate for the formation of palladium; platinum(II) acetylacetonate, platinum(II) chloride, platinum(IV) chloride, for the formation of platinum; and others.

To yield the freestanding NIC particles, the core material, e.g., Cu₂S, can be disintegrated (leached out) by dissolution into an appropriate dissolution material which is able to dissolve the core material, e.g., Cu₂S, but substantially incapable of dissolving the cage material, e.g., Ru. Such dissolution material may be selected amongst materials capable of selectively coordinating with the material to be removed, materials capable of reducing or oxidizing the material to be removed and any other suitable solvent material. In such embodiments where the core material composes copper, the dissolving agent is a copper coordinating ligand such as neocuproine, 1,10-phenanthroline, or bathocuproine.

In other embodiments, the dissolution agent is an oxidizing material capable of selectively oxidizing the Cu₂S core.

For certain applications it may be also desirable to form certain predefined populations of cage nanoparticles and also vary the chemical composition of the nanoparticles. Thus, in some embodiments, there is provided a population of NIC and/or NICed particles according to the invention, in a blend of one or more of the following types/groups of nanoparticles:

1) NIC particles of a certain polyhedron shape;

2) NICed particles of a certain shape;

3) NIC particles of different shapes and/or materials; and/or

4) NICed particles having the same cage material but varying core material or NICed particles having the same core material but varying cage material or any combination of the two types of nanoparticles.

A population of NIC and/or NICed particles may comprise a blend of particles of one or more of the above types, in a known pre-determined ratio of particles or comprise a random mixture of such particles. In certain embodiments, a population of particles comprises nanoparticles having a large variety of sizes and shapes, constructed of a single metal/metal alloy or semiconductor materials. In other embodiments, a population of particles may comprise nanoparticles of different shapes and different chemical compositions.

In addition, any of the particle populations of the invention may also comprise at least one type of particle outside of the scope of the present application. Such mixed populations of nanoparticles herein described and nanoparticles known in the art may have advantageous effects suitable for any one application disclosed herein.

The present invention also provides in further aspects thereof various uses of any one of the nanoparticles disclosed herein.

The NIC and/or NICed particles or populations containing them may be used in catalysis. The catalytic reaction is an organic or inorganic reaction involving bond formation and/or bond cleavage. In some embodiments, the particles of the invention are employed in the catalyzed conversion of environmentally threatening pollutants to safer or better tolerated agents. Such pollutants may be arising from the petroleum refinery industries, the motor vehicle industries, from motor vehicle emissions and other sources. The pollutants may be air pollutants, water pollutants, ground pollutants, and may for example, be selected from volatile organic compounds and gaseous pollutants such as nitrogen oxides, sulfur oxides and carbon monoxide.

Thus, in some embodiments, the particles of the invention are employed in a hydrodesulphurization process for desulfurization of industrial products such as natural gas and petroleum products.

In other embodiments, the particles are employed in a hydrodenitrogenation (or hydrodenitrification) process for removal of nitrogen from industrial products.

In some embodiments, the particles of the invention are employed as catalysts for hydride transfer processes and hydrogenations to be employed for the preparation of feed stock and fuel chemicals such as formate, methane, hydrogen, methanol and other alcohols, etc., as well as reductive hydrogenations of nicotinamide adenine dinucleotide phosphate (NADP) and similar analogues for the development of synthetic photosynthesis.

The NIC or NICed particles or populations containing them, neat or in solution, in accordance with the invention may be used as photocatalysts in a variety of photo-induced reactions.

When the NICed particles employed in photocatalysis, in accordance with the present invention, are irradiated (illuminated) with a light source having an energy exceeding the band gap energy of a semiconductor material of the nanoparticles, electrons and positive holes are formed in the form of an electron-hole pair. Once formed, the electrons and positive holes undergo charge separation with one carrier remaining in the first absorbing semiconductor materials, and the other transferred to the second material, at which stage they are capable of evoking various photocatalytic reactions by interacting with neighboring electron acceptor and electron donor molecules. Since the holes so generated have oxidizing power, and the electrons have reducing power, the nanoparticles of the invention acting as photocatalysts can catalyze a reduction-oxidation (redox) reaction as long as electrons and holes are formed, e.g., by light-activation. As the nanoparticles are not consumed in the process and do not lose their ability to undergo the light-induced process described, their function depends on the presence of a light source or their ability to retain charge and undergo such a process even in the absence of light.

Non-limiting examples of such photo-induced reactions may be one or more of water splitting; purifications of water and air from contaminates through e.g., decomposition of such contaminants; deodorization; treatment of industrial effluent and exhaust; chemical transformation of organic contaminants, such as residues from the dye industry into less toxic and more environmentally safe agents; antibacterial applications; anti-fouling applications, and generally any chemical reaction involving reduction-oxidation reactions for the production of a desired intermediate(s) or end product(s) or for the elimination of a harmful contaminate.

In some embodiments, a plurality of NIC particles or NICed particles or any combination thereof is used in the catalysis of a reaction. The use may for example be in a method for photocatalytic reduction of a compound. In such embodiments, the method comprises irradiating a solution comprising a plurality of NICed particles according to the invention and a compound to be reduced with a light source under conditions permitting reduction of said compound. In some embodiments, the light irradiated is visible light.

Thus, the present invention also provides light-activated hybrid nanoparticles, the NICed particles, having an absorption onset in the UV (200-400 nm), and/or to the visible (400-700 nm) and/or to near infrared (NIR) range (0.7-3 μm), for use as photocatalysts and in the constructions of devices incorporating light-induced charge separation.

The present invention also provides in another of its aspects a method of photo-inducing charge separation and transfer of charge carriers to charge acceptors, said method comprising:

1) providing at least one NICed particle, as disclosed herein;

2) contacting said at least one NICed particle with at least one electron acceptor and at least one electron donor (e.g., hole acceptor) in a medium; and

3) optionally, irradiating the medium containing said at least one NICed particle, at least one electron acceptor and at least one electron donor with a radiation in the visible and/or near IR range and optionally UV range; thereby allowing formation of an electron-hole pair in the material interface of said at least one NICed particle and subsequent charge separation and transfer of the electron and hole to said at least one electron acceptor and said at least one electron donor, respectively.

The invention also provides the use of a plurality of NIC particles or NICed particles in the construction of solar cells.

The invention also provides the use of a plurality of NIC particles or NICed particles in the construction of photovoltaic cells.

In another aspect, the invention provides the use of NIC particles as vehicles for the storage and/or delivery of at least one chemical species. Such chemical species may be an atom, an ion, a molecule, a crystal of a different material, a polycrystalline material, a biomaterial, a magnetic particle, and others.

The invention also provides the use of an individual or plurality of NIC particles or NICed particles as electrocatalysts for the electrochemical reduction and/or oxidation of substrate molecules. In some embodiments, the NIC particles or NICed particles are used as catalysts in sensor devices, e.g., for sensing electroactive species such as peroxide, glucose and other electroactive species. This can be realized by NICed particles deposited on suitable electrodes.

### BRIEF DESCRIPTION OF THE DRAWINGS

In order to understand the invention and to see how it may be carried out in practice, embodiments will now be described, by way of non-limiting example only, with reference to the accompanying drawings, in which:

FIGS. 1A-1J is a schematic representation of the synthesis and Transmission Electron Microscope, TEM, characterization of Ru NICed Cu₂S nanoparticles and free Ru NICs.

FIG. 1A is a schematic representation of the synthesis of Ru NICed Cu₂S and free Ru NICs.

FIG. 1B shows TEM of Cu₂S seeds.

FIG. 1C shows High Resolution TEM of Cu₂S seeds indicating single crystallinity of the particle.

FIG. 1D shows Selected Area Electron Diffraction, SAED, (inverted negative) of a superstructure of Cu₂S seeds. The dark spots indicate crystallographic alignment of the Cu₂S seeds within the superstructure.

FIG. 1E shows TEM of Ru NICed Cu₂S nanoparticles.

FIG. 1F shows High Resolution-TEM of Ru NICed Cu₂S nanoparticle indicating single crystallinity of the core.

FIG. 1G shows SAED (inverted negative) of free Ru NICed Cu₂S.

FIG. 1H shows TEM of free RuS₂ NICs.

FIG. 1I shows High Resolution-TEM of a free Ru NIC. Small crystalline regions (˜1 nm) can be observed, but most of the structure shows no lattice fringing.

FIG. 1J shows SAED (inverted negative) of free Ru NICs with rings indexed to metallic Ru.

FIGS. 2A-2D shows X-ray Diffraction patterns:

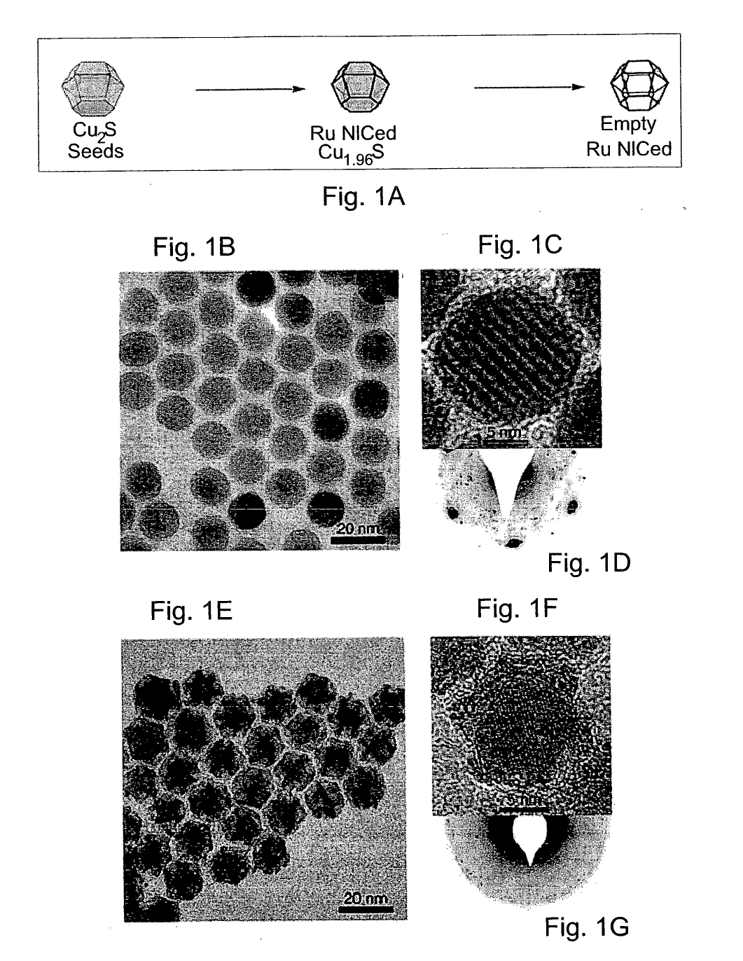

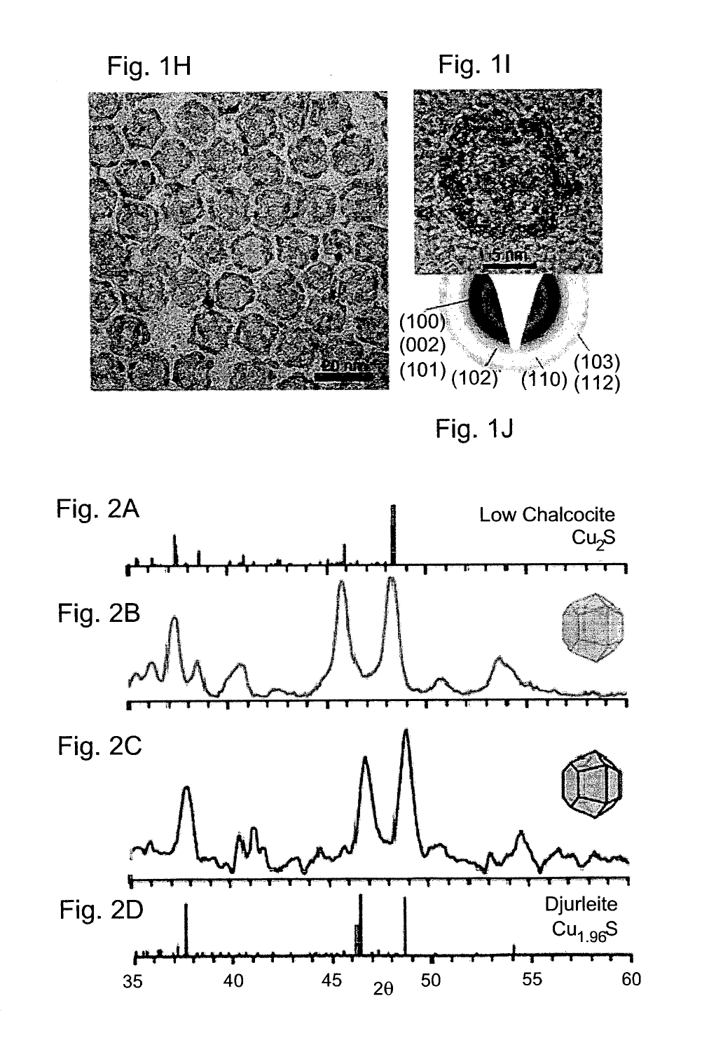

FIG. 1A expected positions and intensities of reflections for low chalcocite (JCPDS 03-065-3816).

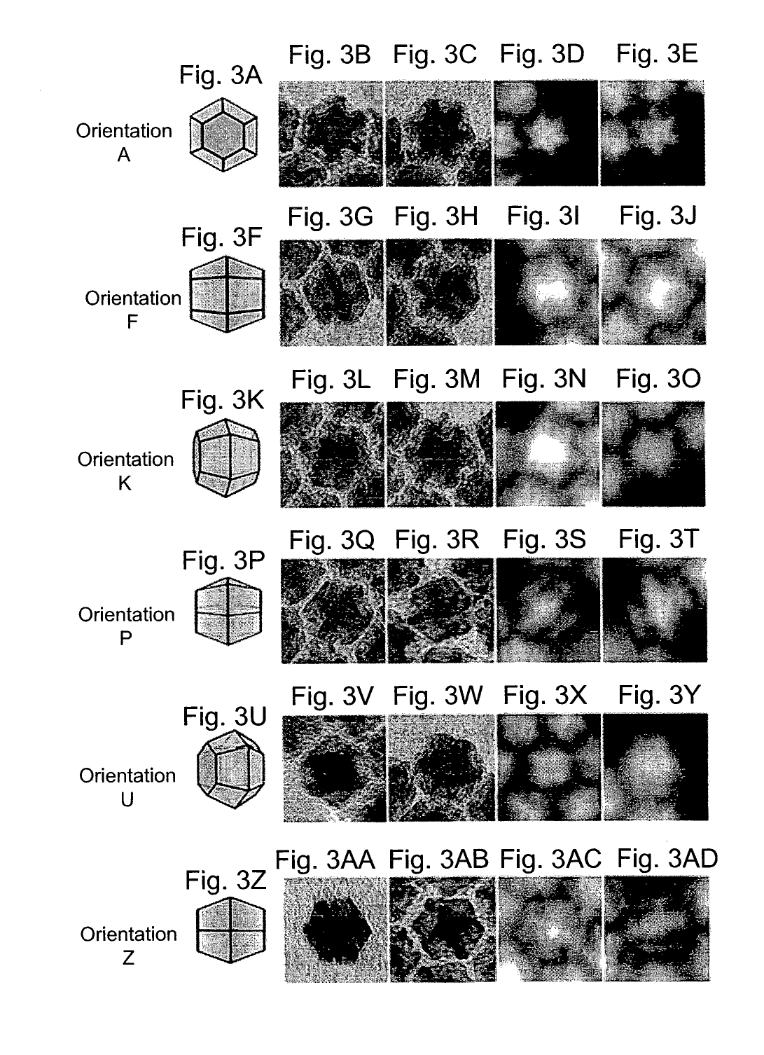

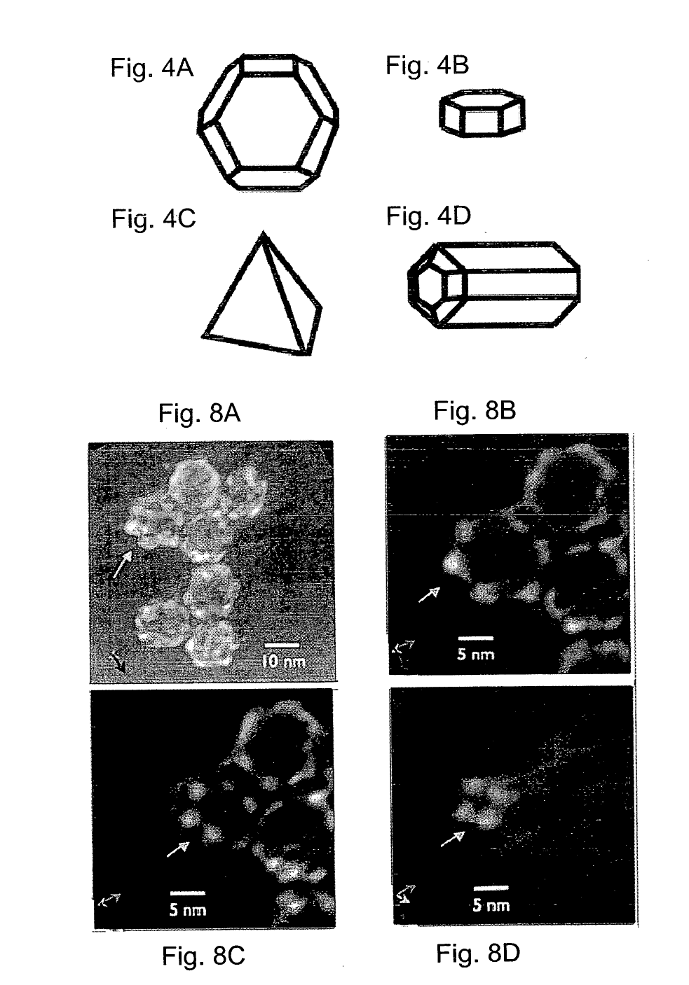

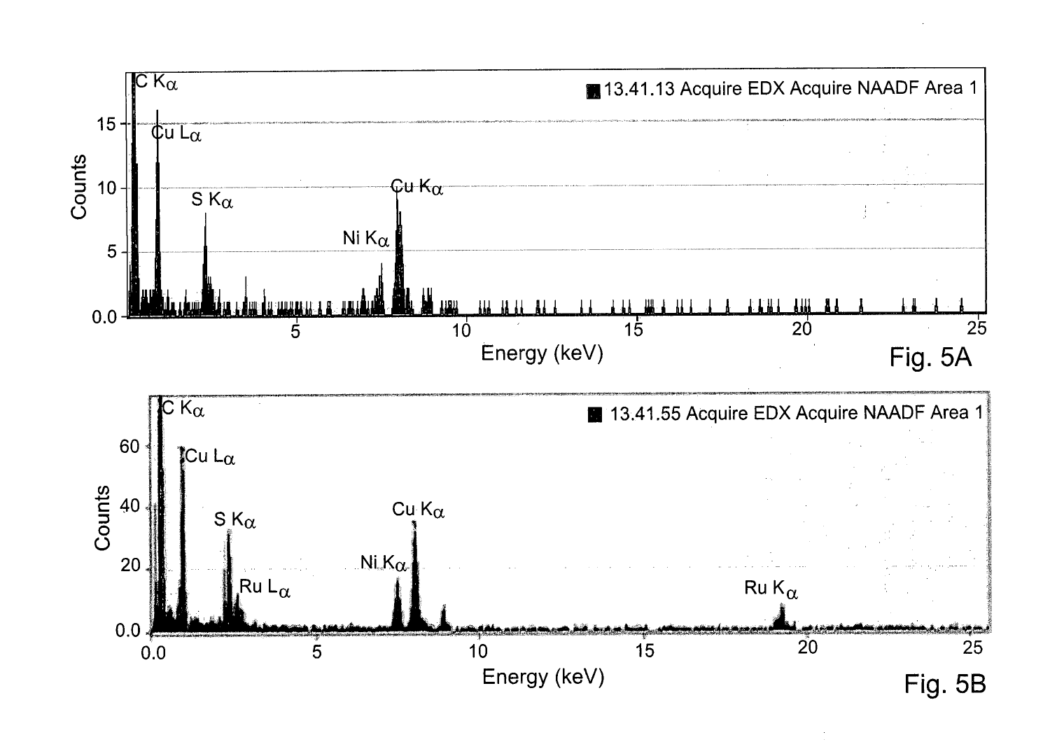

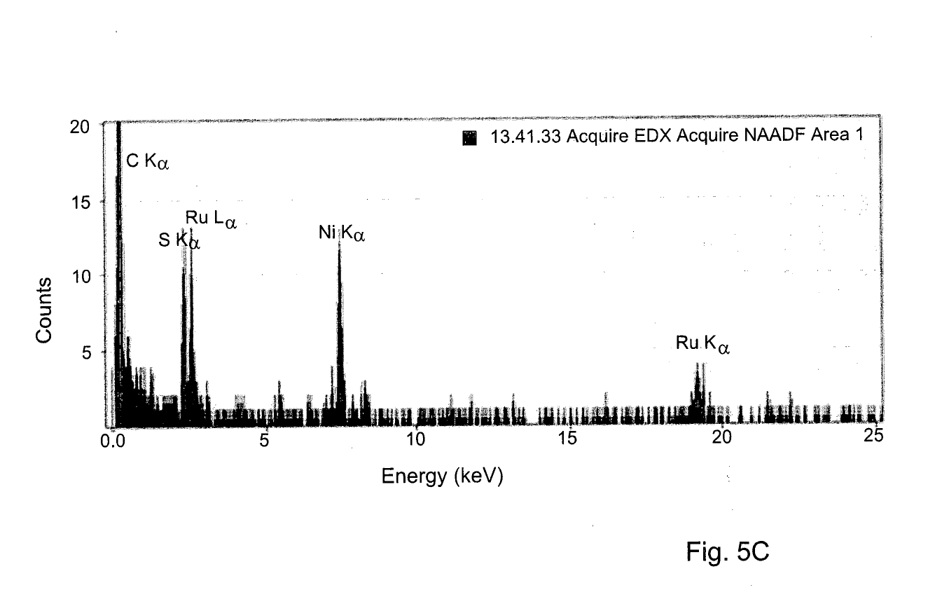

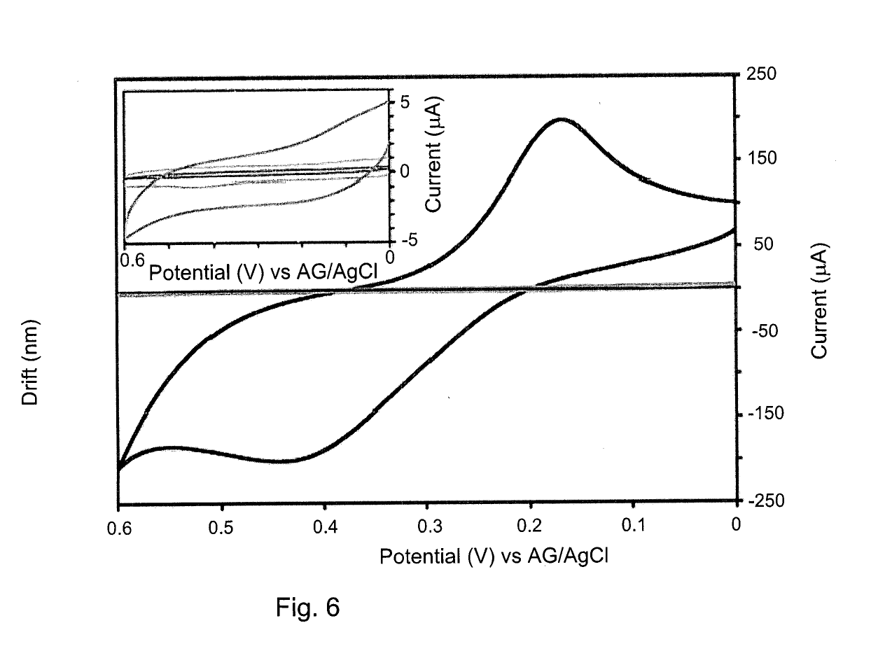

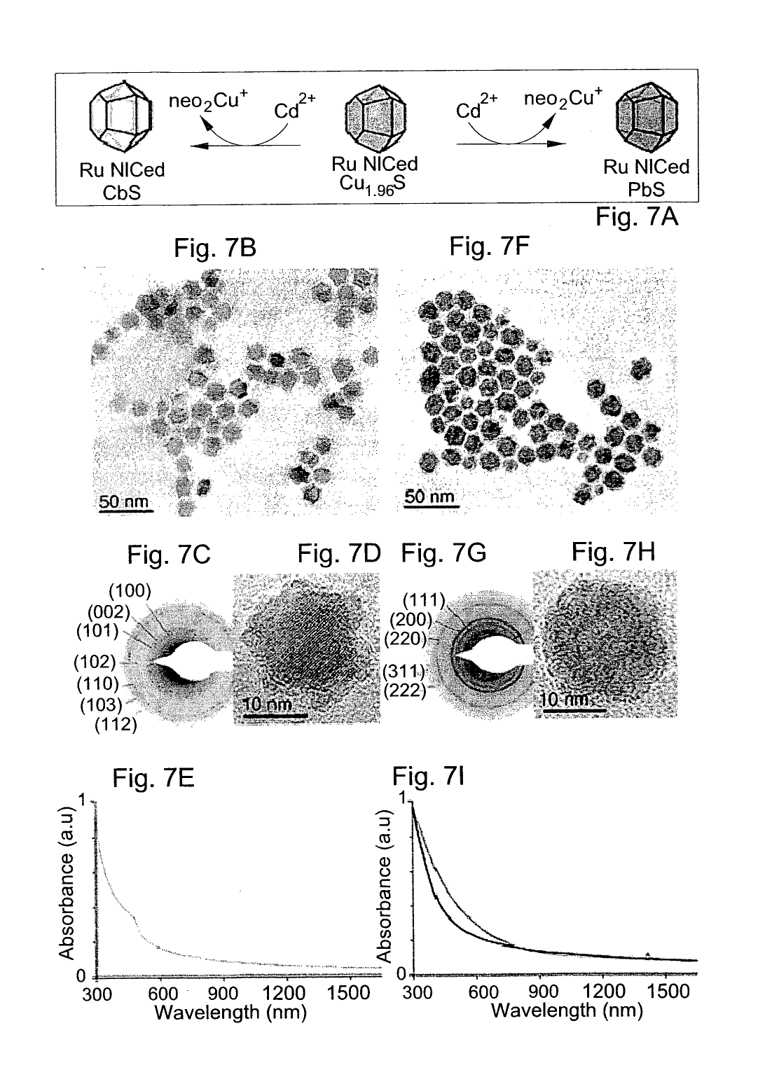

FIG. 2B of Cu₂S seed particles.

FIG. 2C of Ru NICed Cu₂S nanoparticles.

FIG. 2D expected positions and intensities of reflections for Djurelite (JCPDS 00-034-0660).

FIGS. 3A-AD show orientations of the truncated hexagonal biprism shape of the Ru NICed Cu₂S nanoparticles observed by TEM and Scanning Transmission Electron Microscopy (STEM).

FIG. 3A schematic representation of an observed orientation A.

FIGS. 3B-C TEM of particles in orientation A.

FIGS. 3D-E STEM of particles in orientation A.

FIG. 3F schematic representation of an observed orientation F.

FIGS. 3G-H TEM of particles in orientation F.

FIGS. 3I-J STEM of particles in orientation F.

FIG. 3K schematic representation of an observed orientation K.

FIGS. 3L-M TEM of particles in orientation K.

FIGS. 3N-O STEM of particles in orientation K

FIG. 3P schematic representation of an observed orientation P.

FIGS. 3Q-R TEM of particles in orientation P.

FIGS. 3S-T STEM of particles in orientation P.

FIG. 3U schematic representation of an observed orientation U.

FIGS. 3V-W TEM of particles in orientation U.

FIGS. 3X-Y STEM of particles in orientation U.

FIG. 3Z schematic representation of an observed orientation Z

FIGS. 3AA-AB TEM of particles in orientation Z.

FIGS. 3AC-AD STEM of particles in orientation Z.

FIGS. 4A-4D show additional polyhedron structures for forming NIC and NICed particles according to the invention:

FIG. 4A cuboctahedron.

FIG. 4B hexagonal plate.

FIG. 4C pyramid.

FIG. 4D rod-like.

FIGS. 5A-C show Energy Dispersive X-Ray Spectroscopy (EDS) pictures:

FIG. 5A of Cu₂S nanoparticles.

FIG. 5B of Ru NICed Cu₂S nanoparticles; and

FIG. 5C of free Ru NICs. Nickel signals are a result of the nickel grids used as a support for TEM analysis.

FIG. 6 shows H₂O₂ sensing with Ru NICed Cu₂S particles. Presented are Cyclic Voltammetry (CV) curves in 0.2 mM H₂O₂ and 0.1M KCl of ITO electrodes modified with Cu₂S seed particles (thin black), empty Ru NICs (thick grey), Ru NICed Cu_{1.96}S (thick black), and bare ITO (thin grey) at a scan rate of 50 mV/s. Inset shows an expanded view of the low current curves of the Cu₂S seeds, Ru NICs and bare ITO.

FIG. 7A-I demonstrates cation exchange to give Ru nano-inorganic caged CdS and PbS:

FIG. 7A shows a schematic of the cation exchange process from Ru NICed Cu₂S to Ru NICed CdS and Ru NICed PbS.

FIG. 7B shows TEM of shows Ru NICed CdS.

FIG. 7C shows SAED of Ru NICed CdS.

FIG. 7D shows HR-TEM of Ru NICed CdS.

FIG. 7E shows normalized absorbance of Ru NICed CdS. A rise in the absorbance profile at ˜500 nm is due to the bandgap onset of CdS.

FIG. 7F shows TEM of shows Ru NICed PbS.

FIG. 7G shows SAED of Ru NICed PbS.

FIG. 7H shows HR-TEM of Ru NICed PbS.

FIG. 7I shows normalized absorbance of Ru NICed PbS in black. Normalised absorbance of empty Ru nano-inorganic cages is shown in grey. The PbS sample showed relatively increased absorbance throughout the visible region compared with the bare cages.

FIGS. 8A-D show tomography of empty Ru cages voxel view and slices of the tomogram to show the internal structure of a single cage marked by the arrow.

FIG. 8A is a voxel view, where each pixel is attributed opaqueness with correspondence to its intensity value.

FIG. 8B shows a slice through the tomogram, showing the median plane with its hexagonal shape.

FIG. 8C shows a slice through the tomogram, showing the top hexagonal plane.

FIG. 8D show a slice through the tomogram at an angle tilted compared to the others slices as denoted by the directional arrows. A rectangular facet on a side plane is seen.

### DETAILED DESCRIPTION OF EMBODIMENTS

Cu₂S is a semiconductor with a bulk band gap in the visible range. Cu₂S has large extinction coefficient and is thus used as a material for solar energy applications. Cu₂S is also known as an electrocatalyst for peroxide and glucose sensing. Ru is an important catalytic metal for hydrodesulphurization and hydrodenitridization, oxidations, and reductions. Therefore, the Ru NIC particles of the present invention are valuable catalysts themselves.

Additionally, RuS₂ and RuO₂ are two of the best catalysts known for the photo- and photo-electrochemical oxidation of water. As such, hybrids of copper sulfides and RuS₂ or RuO₂, as in the form of RuS₂—Cu₂S or RuO₂—Cu₂S nanoparticles of the present invention are important photocatalysts for water splitting. As well, copper sulfides have been employed as oxidation catalysts for hydrosulfide ions for water purification. Therefore, hybrids of the catalytic oxidation properties of copper sulfide and ruthenium sulfide may be an important material for catalytic and photocatalytic water purification.

The Cu₂S nanoparticle crystals (seeds in the formation of the NICed and NIC nanoparticles) were prepared by a modification of literature procedures [13, 14] whereby copper(II) acetylacetonate was heated in the presence of a long chain thiol. The thiol acts as solvent, surfactant and sulfur source in the synthesis of the nanoparticles. The resulted Cu₂S particles were faceted and were 17.3 nm in diameter with a standard deviation of 1.4 nm (n=80) (FIG. 1B). Selected Area Electron Diffraction (SAED) of one of these structures gives strong spots (FIG. 1D), rather than rings indicating a preferred crystallographic orientation of the nanoparticles. SAED, X-ray diffraction (XRD) (FIG. 2A,B) and Energy Dispersive Spectroscopy (EDS) (FIG. 5A) were consistent with low-Chalcocite nanoparticles. HR-TEM indicated the particles were single crystals (FIG. 1C).

Ru NICed Cu₂S nanoparticles were prepared, as demonstrated for the purpose of clarity in FIG. 1A, by transferring the Cu₂S nanoparticles to a high boiling point amine and the addition of a ruthenium precursor at high temperature (d=15.1, standard deviation 1.1 nm, n=77). Careful observation of the prepared structures seen by TEM and STEM indicated that the Cu₂S have reacted with the ruthenium only at the crystal edges of the particles. The highly reactive edges of the Cu₂S nanoparticles provided a selective site for reaction, nucleation and growth of the Ru frame forming a nano-inorganic cage inclosing the Cu₂S. Thus, by changing the size and/or shape of the original nanoparticles, it was possible to control the size and shape of the frame (FIG. 1E, FIGS. 3A-AD).

The shape of the specific NICed particles of the example is a truncated hexagonal biprisim and is consistent with shapes of Cu₂S crystallites observed elsewhere [15]. HR-TEM indicated the particles were still single crystalline across the core of the particles (FIG. 1F). EDS was consistent with the presence of both Cu₂S and Ru (FIG. 5B). XRD indicated the crystal structure has changed to the closely related Cu₂₋ₓS Djurelite structure (FIG. 2C,D). The copper deficient structure was reasonable considering the Ru³⁺ precursor must necessarily be reduced by the Cu¹⁺ in order for Ru to be formed. This is further evidenced by the blue color of Cu²⁺ amine complexes observed during work-up.

The formation of freestanding nanoinorganic cages, or NICs, i.e., the liberation of the Ru cages, was achieved by the complexation of the Cu'⁺ with neocuproine thereby dissolving away the Cu₂S core (FIG. 1H). The HR-TEM of the resulting freestanding cages indicated they had very small crystalline domains of approximately 3-5 nm in size but are largely amorphous (FIG. 1I). This is further supported by the broad nature of the rings observed in SAED (FIG. 1J). EDS is consistent with the formation of Ru and the successful removal of the copper (FIG. 5C).

Ru NICed Cu₂S shows remarkable synergistic properties as an electrocatalyst towards H₂O₂ sensing as a result of the unique cage shape and material combination. Copper(I) sulfide nanoparticles were demonstrated as excellent electrocatalysts for peroxide sensing but required carbon nanotubes as a supporting conducting material for sufficient activity [1,6]. FIG. 6 shows CV curves of electrodes modified by the nanoparticles. Compared to the blank electrode, a film of Cu₂S seeds blocked the current, because the peroxide redox couple occurs at voltages between the valence and conduction band energies. A deposition of empty Ru cages amplified the currents by a factor of ˜4-5 likely due to their conductive and porous nature, which increased the effective surface area of the electrode. However, in neither case were the oxidation and reduction peaks of H₂O₂ distinct. In contrast, the hybrid Ru NICed Cu₂S provided distinct redox peaks and remarkably, currents two orders of magnitude larger than the bare electrode. The electrochemical H₂O₂ sensing is achieved only by the synergy of the two powerful concepts of hybrid nanoparticles and cages; a conductive percolating path for electrons is provided by the Ru metal cages which are also in intimate contact with the exposed Cu₂S surfaces which only then can act as the redox catalyst.

The open cage structure of the filled nano-inorganic caged (NICed) particles not only provides opportunities for reaction with the interior semiconductor but also for material modification. Copper sulfides are known to readily cation exchange while leaving the initial particle shape intact. Through ion exchange, these caged nanoparticles are therefore a gateway to nano-inorganic caged particles with other semiconductors as cores, and in this manner, the properties such as the optical bandgap may be tuned.

To this end, Ru NICed particles of Cu₂S were transformed into Ru NICed particles of CdS and PbS through cation exchange (FIG. 7A). TEM of both products show the characteristic contrast patterns of the cage structure (FIGS. 7B, F). HRTEM (FIGS. 7D,H), SAED (FIGS. 7 C,G) and Energy Dispersive X-ray Spectroscopy (EDS) provided direct evidence for the formation of the CdS and PbS cores, respectively. While the addition of Cd²⁺ formed single crystal hexagonal CdS cores, the cubic PbS cores were multi-crystalline. The absorbance spectra of both products were clearly altered by the modifications; neither show the broad NIR plasmon band of Cu_{1.96}S observed for the original caged particles, yet the broad absorbance of the ruthenium cages was maintained as evidenced by the non-zero absorbance at long wavelengths (FIGS. 7E,I).

The absorbance spectra also exhibit the features of the new semiconductor cores. This demonstrates the enrichment of the family of hybrid metal-semiconductor nano-inorganic cages via a straightforward reaction. Moreover, copper sulfide is closely related to other technologically important semiconductors such as CuInS₂. This introduces further opportunities for expanding the selection of materials in the form of hybrid nano-inorganic cages. Interesting nano-mechanical and optical properties of these systems may be utilized in, e.g., catalysis and photocatalysis.

### Preparation of Cu₂S Nanoparticles

Copper(II) acetylacetonate (265 mg, 1.0 mmol) was suspended in 25 mL of dodecanethiol. The mixture was bubbled with argon for 30 min and then heated quickly to 200° C. for 1 h. Upon heating, the solution turned initially yellow and then brown as the reaction progressed. Particles were isolated by allowing the mixture to settle and the supernatant was removed. Two washes with dry isopropanol were followed by two washes with dry chloroform while maintaining an inert atmosphere. The products were suspended in 20 mL of chloroform. The concentration of copper in the solution was determined by digesting an aliquot of known volume in neocuproine and chloroform. Absorbance of this solution was compared to standards of the resultant copper(I) neocuproine complex to determine concentration of Cu in the nanoparticle suspension.

### Example 1

### Preparation of Ru NICed Cu₂S Nanoparticles

3 mL of Cu₂S/chloroform (15 umol of copper) solution was added to 2.0 g of octadecylamine. The chloroform was removed in vacuo. The solution was heated to 200-210° C. for 30 minutes. A suspension of ruthenium (III) acetylacetonate (1 mg, 2.5 μmol) and octylether (1 mL) was added and the entire solution stirred and at 205-210° C. for 1 h. Particles were isolated by repetitive dissolution of the excess surfactant in warm isopropanol (60-70° C.) followed by centrifugation, yielding a black precipitate and a blue supernatant. The precipitate was suspended in chloroform and centrifuged. The yellow supernatant was collected as a solution of the desired NICed Cu₂S nanoparticles.

### Example 2

### Liberation of the Ru NICs

A chloroform solution of the Ru NICed Cu₂S nanoparticles was prepared (Optical Density (OD)=0.5 @ 400 nm). Neocuproine (10 mg, 48 μmol) was added and the solution was stirred for 4 d. The solvent was removed by argon flush and the precipitate washed three times with ethanol. Liberated Ru NICs cages were readily suspended in chloroform for further characterization.

As demonstrated in FIGS. 8A-D, the material of the Ru cage is nonporous at the resolution provided by the TEM tomogram.

### Example 3

### Amperometric Detection of Peroxide with Ru NICed Cu₂S

Cyclic Voltammetry (CV) experiments were performed on a CH Instruments Electrochemical Analyzer 630B, in a 3 electrode configuration. The counter electrode and reference electrode were graphite and Ag/AgCl (KCl sat.), respectively. Working electrodes modified by a film of nanoparticles were prepared by drop casting chloroform solutions of the nanoparticles on ITO coated glass substrates (70-100 Ω/sq). The area of the submersed working electrodes was 1.3 cm². Solutions were prepared of 0.1 mM KCl and 0.2 mM H₂O₂ in triply distilled water. The potential was scanned from 0.0 V to 0.6 V (vs Ag/AgCl) at a scan rate of 0.05 V/s.

### Example 4

### Cation Exchange to Ru NICed CdS and Ru NICed PbS

Solutions of Ru NICed Cu_{1.96}S particles (0.70 mL, [Cu¹⁺]=10 mM, toluene), neocuproine (0.80 mL, 20 mM, toluene), cadmium acetate hydrate (0.80 mL, 10 mM, methanol), and lead acetate hydrate (10 mM, methanol) were prepared in a nitrogen-filled glove box and added together along with a small amount of octadecylamine (10 mg) to aid dissolution of the product. The solution was stirred in excess of five hours in the glove box and turned increasingly yellow from the formation of the copper neocuproine complex. Purification was performed after the evaporation of the solvent. Isopropanol was added followed by centrifugation at 5000 rpm. The supernatant was removed and the purification process repeated twice more. The purified cation exchanged product readily suspended in chloroform for characterization. Solutions of the cadmium ion exchange products appeared pale yellow-green and Energy Dispersive X-ray Spectroscopy (EDS) confirmed the presence of Cd, S and Ru and only trace amounts of copper, whereas the lead products were brown and EDS indicated the presence of PbS, S, and Ru.

1-63. (canceled)

64. A hybrid nanostructure comprising a core of a first inorganic material, said core material being in the form of a polyhedron defined by a plurality of faces connected to each other via straight edges, said core material having a continuum of a second inorganic material substantially only on its edges, said first and second inorganic materials are different.

65. The hybrid according to claim 64, wherein said first inorganic material is or comprises of an element of Groups IIIB, IVB, VB, VIIB, VIIB, VIIIB, IB, IIB, IIIA, IVA and VA of block d of the Periodic Table of the Elements.

66. The hybrid according to claim 65, wherein said element is selected from Sc, Ti, V, Cr, Mn, Fe, Ni, Cu, Zn, Y, Zr, Nb, Tc, Ru, Mo, Rh, W, Au, Pt, Pd, Ag, Mn, Co, Cd, Hf, Ta, Re, Os, Ir and Hg.

67. The hybrid according to claim 64, wherein said second inorganic material is or comprises an element of Groups IIIB, IVB, VB, VIIB, VIIB, VIIIB, IB, IIB, IIIA, IVA and VA of block d of the Periodic Table of the Elements.

68. The hybrid material according to claim 67, wherein said second inorganic material is or comprises a transition metal selected from Sc, Ti, V, Cr, Mn, Fe, Ni, Cu, Zn, Y, Zr, Nb, Tc, Ru, Mo, Rh, W, Au, Pt, Pd, Ag, Mn, Co, Cd, Hf, Ta, Re, Os, Ir and Hg.

69. The nanostructure according to claim 64, wherein said first inorganic material is or comprises a semiconductor material selected from Group II-VI, Group III-V, Group IV-VI, Group III-VI, and/or Group IV semiconductors.

70. The nanostructure according to claim 69, wherein said first inorganic material is or comprises a semiconductor material selected from CdSe, CdS, CdTe, ZnO, ZnSe, ZnS, ZnTe, HgS, HgSe, HgTe, CdZnSe, InAs, InP, InN, GaN, InSb, InAsP, InGaAs, GaAs, GaP, GaSb, AlP, AlN, AlAs, AlSb, CdSeTe, ZnCdSe, PbSe, PbTe, PbS, PbSnTe, Tl₂SnTe₅, RuS₂, RuO₂, MoS₂, MoO₃, RhS₂, RuO₄, TiO₂, WS₂ and WO₂.

71. The nanostructure according to claim 64, wherein the second inorganic material is or comprises a semiconductor material selected from Group II-VI, Group III-V, Group IV-VI, Group III-VI, and/or Group IV semiconductors.

72. The nanostructure according to claim 71, wherein said second inorganic material is or comprises a semiconductor material selected from CdSe, CdS, CdTe, ZnSe, ZnS, ZnTe, ZnO, TiO₂, HgS, HgSe, HgTe, CdZnSe, InAs, InP, InN, GaN, InSb, InAsP, InGaAs, GaAs, GaP, GaSb, AlP, AlN, AlAs, AlSb, CdSeTe, ZnCdSe, PbSe, PbTe, PbS, PbSnTe, Tl₂SnTe₅, RuS₂, RuO₂, MoS₂, MoO₃, RhS₂, RuO₄, WS₂ and WO₂.

73. The hybrid according to claim 64, wherein the second inorganic material is of a material selected from Ru, Mo, Rh, W, CdSe, CdS, CdTe, ZnSe, ZnS, ZnTe, HgS, HgSe, HgTe, CdZnSe, InAs, InP, InN, GaN, InSb, InAsP, InGaAs, GaAs, GaP, GaSb, AlP, AlN, AlAs, AlSb, CdSeTe, ZnCdSe, PbSe, PbTe, PbS, PbSnTe, Tl₂SnTe₅, RuS₂, RuO₂, MoS₂, MoO₃, RhS₂, RuO₄, WS₂ and WO₂ and the first inorganic material is selected amongst copper sulfides.

74. The hybrid according to claim 73, wherein the second inorganic material is of a material selected from Ru, Mo, Rh, W, RuS₂, RuO₂, MoS₂, MoO₃, RhS₂, RuO₄, WS₂ and WO₂ and said first inorganic material is Cu₂S.

75. The hybrid according to claim 64, wherein said first inorganic material is Cu₂S and said second inorganic material is RuS₂.

76. A hollow nanostructure having a structure defined by the edges of a polyhedron, each of said edges being composed of a continuum of inorganic material, excluding gold hollow nanostructure in the form of a nanocube.

77. The nanostructure according to claim 76, wherein the inorganic material is substantially a material continuum of the inorganic material in an amorphous form, in a crystalline form or a polycrystalline form.

78. The nanostructure according to claim 77, wherein said inorganic material is or composes an element of Groups IIIB, IVB, VB, VIIB, VIIB, VIIIB, IB, IIB, IIIA, IVA and VA of block d of the Periodic Table of the Elements.

79. The nanostructure according to claim 76, wherein said inorganic material composes a semiconductor material selected from Group II-VI, Group III-V, Group IV-VI, Group III-VI, and/or Group IV semiconductors.

80. A method for the preparation of a nanostructure according to claim 64, the method comprising:
(a) providing a nanoparticle of a first inorganic material, said nanoparticle having a polyhedron structure; and
(b) contacting said nanoparticle with a second inorganic material, or a precursor thereof, permitting deposition of said second inorganic material substantially onto the edges of the polyhedron structure of said nanoparticle, to obtain a hybrid nanoparticle of said first and said second inorganic materials.

81. A method for the preparation of a nanostructure according to claim 76, the method comprising:
(a) providing a nanoparticle of a first inorganic material, said nanoparticle having a polyhedron structure;
(b) contacting said nanoparticle with a second inorganic material, or a precursor thereof, permitting deposition of said second inorganic material substantially onto the edges of the polyhedron structure of said nanoparticle, to obtain a hybrid nanoparticle of said first and said second inorganic materials; and
(c) selectively disintegrating the first inorganic material of said hybrid nanoparticle to thereby obtain a substantially hollow nanostructure of a second inorganic material.

82. A light-activated hybrid nanoparticle comprising a core of a first inorganic material, said core material being in the form of a polyhedron defined by a plurality of faces connected to each other via straight edges, said core material having a continuum of a second inorganic material substantially only on its edges, said first and second inorganic materials are different.

83. The nanoparticle according to claim 82 having an absorption onset in the UV (200-400 nm), visible (400-700 nm) and/or the near infrared (NIR) range (0.7-3 μm).

84. Use of a nanoparticle according to claim 82 as a photocatalyst.

85. Use of a nanostructure according to claim 76 and/or a hybrid nanostructure according to claim 64 in a photocatalytic reaction.

86. A method for photocatalytic reduction of a material, said method comprises irradiating a solution comprising a plurality hybrid nanoparticle according to claim 64 and a material to be reduced with a light source under conditions permitting reduction of said material.

87. A method of photo-inducing charge separation and transfer of charge carriers to charge acceptors, said method comprising:
1) providing at least one hybrid nanoparticle according to claim 64;
2) contacting said at least one hybrid nanoparticle with at least one electron acceptor and at least one electron donor in a medium; and
3) optionally, irradiating the medium containing said at least one hybrid nanoparticle, at least one electron acceptor and at least one electron donor with a radiation in the visible, near IR range and/or optionally UV range; thereby allowing formation of an electron-hole pair in the material interface of said at least one nanoparticle and subsequent charge separation and transfer of the electron and hole to said at least one electron acceptor and said at least one electron donor, respectively.
